(19) United States
(12) Patent Application Publication
(10) Pub. No.: US 2021/0193586 A1
(43) Pub. Date: Jun. 24, 2021

(54) CRYPTOGRAPHIC SYSTEM-IN-PACKAGE (CSIP)

(71) Applicant: BAE SYSTEMS Information and Electronic Systems Integration Inc., Nashua, NH (US)

(72) Inventors: Roman KHAZANOVICH, Centereach, NY (US); David C. RINGLEN, Coram, NY (US)

(73) Assignee: BAE SYSTEMS Information and Electronic Systems Integration Inc., Nashua, NH (US)

(21) Appl. No.: 16/718,586

(22) Filed: Dec. 18, 2019

(51) Int. Cl. H01L 23/552; H01L 23/498; H01L 23/31; H01L 25/18

(52) U.S. Cl. CPC H01L 23/552; H01L 25/18; H01L 23/3107; H01L 23/49816

(57) ABSTRACT

A Cryptographic System-in-Package (CSiP) including a built in TEMPEST shield surrounding the sides and the top of the device. In some cases the TEMPEST shield is metal and acts as a thermal path to conduct heat off of the CSiP. In some cases, the TEMPEST shield comprises a microscopic wire mesh and/or includes a power supply filter to block information leakage on the input voltage pins, a ball grid array (BGA) with ground encompassing the full perimeter the bottom of the package, and an encapsulation layer.

### STATEMENT OF GOVERNMENT INTEREST

This disclosure was made with United States Government support under Contract No. W58RGZ-13-D-0048 awarded by the U.S. Army. The United States Government has certain rights in this invention.

### FIELD OF THE DISCLOSURE

The present disclosure relates to cryptographic computers (cryptos) and more particularly to creating a size, weight and power (SWaP) reduction in a cryptographic computer using system-in-package techniques.

### BACKGROUND OF THE DISCLOSURE

Currently available cryptographic computers (cryptos) can be divided into two categories: applique and embedded. The main difference between the two is that an applique crypto is a self-contained module whereby all of the security requirements such as TEMPEST, INFOSEC, and the like are handled within an applique enclosure. None of the security burden is placed on the system that hosts the crypto. In contrast, an embedded crypto relies on system level protections whereby the security boundaries are expanded out to the system level rather than being localized to the crypto.

In NSA jargon, encryption devices are often called blackers, because they convert “red” signals to black. The red/black concept, sometimes called the red-black architecture or red/black engineering, refers to the careful segregation in cryptographic systems of signals that contain sensitive or classified plaintext information (a.k.a. red signals) from those that carry encrypted information, or ciphertext (a.k.a. black signals). Red/black terminology is also applied to cryptographic keys. Black keys are encrypted with a “key encryption key” (KEK) and are therefore benign. Red keys are not encrypted and must be treated as highly sensitive material

TEMPEST is a U.S. National Security Agency specification and a NATO certification referring to any spying on information systems via leaking emanations, including unintentional radio or electrical signals, sounds, and/or vibrations. TEMPEST covers both methods relating to spying on others and methods of shielding equipment against such spying. Protection efforts are also known as emission security (EMSEC), which is a subset of communications security (COMSEC). TEMPEST standards specify shielding or a minimum physical distance between wires or equipment carrying or processing red and black signals.

Using a security boundary of an applique crypto is very appealing, but typically the size and weight burden is significant. An applique crypto typically requires a printed wiring board (PWB), components, connectors, security features, and a rigid chassis. A PWB is a circuit board blank created by etching away material thereby exposing non-conductive lands between conductive traces. While an embedded crypto generally requires less size and weight than an applique, the footprint that it requires is significant. Each component that makes up the crypto requires printed circuit board (PCB) space and PCB routing layers. Additionally, the security burden for an embedded crypto is shifted onto the system.

Wherefore it is an object of the present disclosure to overcome the above-mentioned shortcomings and drawbacks associated with conventional cryptographic computers (cryptos).

### SUMMARY OF THE DISCLOSURE

One aspect of the present disclosure is a cryptographic system-in-package (CSiP), comprising: a plurality of discrete components located within a single system-in-package (SiP); a TEMPEST shield surrounding a plurality of sides and a top of the single system-in-package (SiP) enabling the CSiP. In one example the TEMPEST shield is metal and acts as a thermal path to conduct heat off of the system-in-package (SiP). A filter can be used for a power supply input to block information leakage on input voltage pins.

One embodiment of the cryptographic system-in-package is where the power supply is not required to be additionally TEMPEST protected. In some cases, the plurality of discrete components comprises one or more of a memory, a processor/FPGA, a RAM, and a flash memory. In certain embodiments, the plurality of discrete components further comprises a temperature sensor and/or a voltage monitor.

Another embodiment of the cryptographic system-in-package is wherein the TEMPEST shield further comprises a ball grid array (BGA) with ground encompassing the full perimeter of a bottom of the system-in-package (SiP). In some cases, a ball spacing is about 1 mm in order to mitigate EMI radiation.

Yet another embodiment of the cryptographic system-in-package further comprises a polymer encapsulation layer for making physical penetration of the system-in-package (SiP) evident via visual inspection. In certain embodiments, the metal of the TEMPEST shield comprises a microscopic wire mesh covering the system-in-package (SiP).

These aspects of the disclosure are not meant to be exclusive and other features, aspects, and advantages of the present disclosure will be readily apparent to those of ordinary skill in the art when read in conjunction with the following description, appended claims, and accompanying drawings.

### BRIEF DESCRIPTION OF THE DRAWINGS

The foregoing and other objects, features, and advantages of the disclosure will be apparent from the following description of particular embodiments of the disclosure, as illustrated in the accompanying drawings in which like reference characters refer to the same parts throughout the different views. The drawings are not necessarily to scale, emphasis instead being placed upon illustrating the principles of the disclosure.

FIG. 1 is a perspective view of one embodiment of a conventional implementation of a cryptographic computer circuit card assembly (right) side-by-side with one embodiment of a Cryptographic System-In-Package (CSiP) (left) according to the principles of the present disclosure, where both are shown in a mezzanine circuit card assembly form factor.

FIG. 2A is a diagram of one embodiment of a conventional cryptographic computer mezzanine circuit card assembly mated to a host carrier card.

FIG. 2B is a diagram of one embodiment of a Cryptographic System-In-Package (CSiP) using the same components shown in FIG. 2A, according to the principles of the present disclosure.

FIG. 3A shows a perspective view of one embodiment of a conventional cryptographic computer.

FIG. 3B shows a perspective view of one embodiment of a Cryptographic System-In-Package (CSiP) using the same components shown in FIG. 3A, according to the principles of the present disclosure.

FIG. 4 shows a perspective view of one embodiment of a conventional crypto (top) contrasted with one embodiment of a Cryptographic System-In-Package (CSiP) (bottom) according to the principles of the present disclosure using the same components, where both are shown in a mezzanine circuit card assembly form factor.

FIG. 5 shows one embodiment of a bottom side of a Cryptographic System-In-Package (CSiP) having a ball grid array (BGA) with 1 mm spacing.

### DETAILED DESCRIPTION OF THE DISCLOSURE

There is a continuous market-wide push to reduce Size, Weight, and Power (SWaP) for all electronic systems. This push affects all industries, especially equipment deployed in military and aerospace applications. One of the problems that currently exists in the secure communications space, for example in Identification Friend or Foe (IFF) and Common Data Link (CDL) radio space, is the SWaP of the currently available cryptographic computers (cryptos). Another problem that currently exists in the industry is the schedule and cost penalty for the system level government agency security certification process. A significant certification penalty is incurred every time that a crypto is embedded into a new system. The scope of the certification process largely depends on how the security boundaries are assigned within the system. According to the principles of the present disclosure, one aspect of a secure communication system that lends itself to a SWaP reduction is the crypto. Cryptos are present in almost all military communications systems that require encrypting and decrypting of information that is vital to national security.

One embodiment of the present disclosure uses 3D stacked die packaging technology to integrate a plurality of discrete components that are required to make a crypto from a single System-in-Package (SiP) with a TEMPEST boundary. Traditionally a SiP contains several chip dies including a processor/FPGA, RAM, flash, passive (bypass) components, and the like. In one embodiment, additional security functions such as temperature sensors and/or voltage monitors will also be included in the CSiP. Additional security features could force the CSiP into reset conditions when triggered.

In this embodiment of the present disclosure, the Cryptographic System-in-Package (CSiP) also includes a built in TEMPEST shield surrounding the sides and the top of the device. In one embodiment, a metal TEMPEST shield also acts as a thermal path to conduct heat off of the CSiP, much like a heat sink. Using the latest available technology may also minimize the power draw of the crypto thereby also reducing the need to remove heat.

One embodiment of the CSiP of the present disclosure includes a power supply filter to block information leakage on the input voltage pins. This would mitigate Differential Power Analysis (DPA) side channel attacks and allow a black power supply to power the CSiP. A black power supply is not required to be additionally TEMPEST protected. In certain embodiments, the bottom of the package would comprise a ball grid array (BGA) with ground encompassing the full perimeter of the CSiP at a ball spacing of about 1 mm in order to mitigate EMI radiation.

In one embodiment, the outward perimeter row of the BGA pins is tied to ground and spaced 1 mm apart to offer protection for electromagnetic signals that may radiate out of the bottom side of the device (See, e.g., FIG. 5). These balls are soldered to a ground trace surrounding the CSiP perimeter. A 1 mm ball spacing allows electromagnetic radiation wavelengths (λ) smaller than 1 mm to pass through unattenuated. A λ=1 mm translates to a cutoff frequency of ˜299.8 GHz. Frequencies above ˜299.8 GHz will pass through the 1 mm aperture without attenuation, and frequencies below ˜299.8 GHz will be attenuated due to the shielding. At frequencies below 1.499 GHz, where the 1 mm aperture is λ/200, approximately 40 dB attenuation is achieved. At frequencies below 149.9 MHz, where the 1 mm aperture is λ/2000, approximately 60 dB attenuation is achieved. Considering this level of attenuation as well as the operating frequencies of a FPGA, it is determined that a 1 mm aperture achieved by grounding the outer BGA pins is sufficient to provide the desired TEMPEST protection.

One embodiment of the CSiP of the present disclosure is encapsulated in a polymer making physical penetration of the crypto system very evident via visual inspection. In some cases, industry proven package level security features such as a microscopic wire mesh covering the CSiP may also be included. In that case, when the mesh is broken the device may be rendered inoperable. The additional security features embedded into the package would further alleviate the burden on the overall system to provide security. Shifting as much of the security onus from the system onto the CSiP is very beneficial to future system level security certifications using the same crypto. Similarly, another feature that facilities applying these concepts across different projects is by using a mezzanine card format. A mezzanine card is essentially just a card that attaches to another card. However, the card is a crypto card when it provides crypto functions. Sometimes this card has TEMPEST provisions, and sometimes those provisions are at a system level. In this application the TEMPEST boundary is used at the mezzanine level just to demonstrate that it can be made smaller. The TEMPEST boundary surrounding the mezzanine is modelled after an existing real world system. It should also be noted that throughout this application the crypto is depicted as a mezzanine and the CSiP is installed on that mezzanine. It is important to note that the CSiP could be installed directly on a host card without a mezzanine and the CSiP internal TEMPEST boundary would enable this.

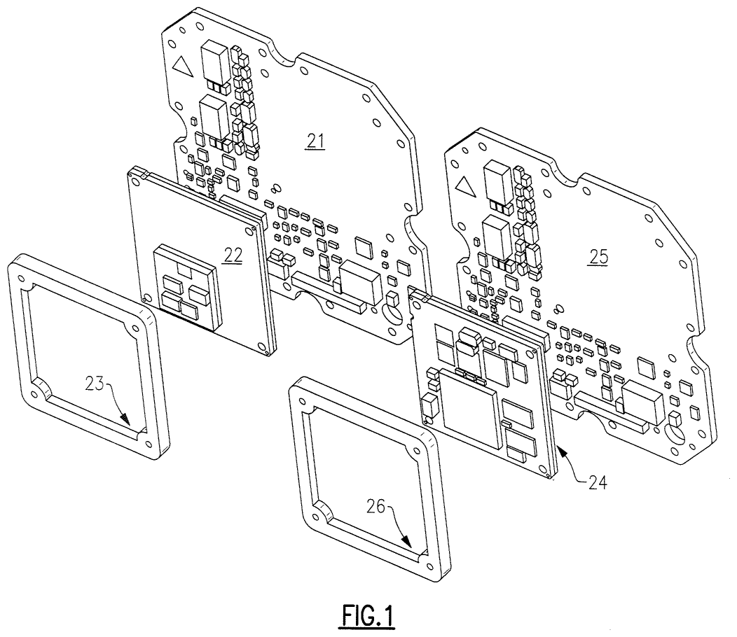

Referring to FIG. 1, a diagram of one embodiment of a conventional implementation of a cryptographic computer circuit card assembly (right) is shown side-by-side with one embodiment of a Cryptographic System-In-Package (CSiP) (left). More specifically, a crypto host circuit card assembly (CCA) (21, 25), or host board, requires cryptographic services in order to perform system mission in many applications. These cryptographic services are provided to the host board by the conventional crypto mezzanine (24), or the presently described crypto mezzanine 22. In certain embodiments, the crypto mezzanine or crypto CCA is mechanically and electrically attached to a host CCA. In some embodiments, a stiffener frame (23, 26) is also present for the purpose of ensuring proper operation under heavy vibration. As noted above, in some cases, the CSiP is mounted directly to the host card.

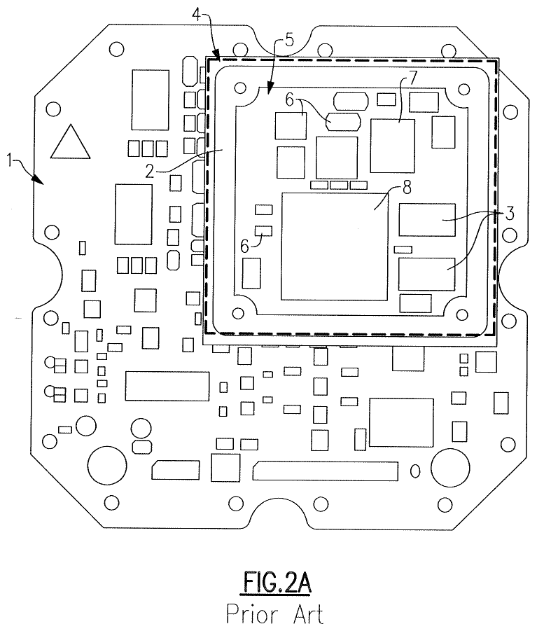

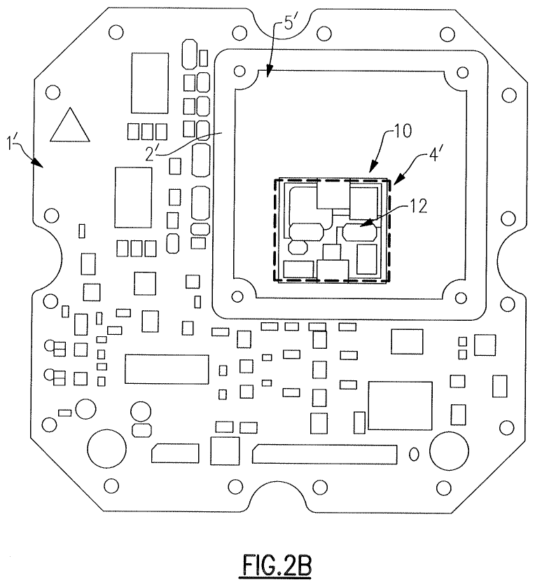

Referring to FIG. 2A, a diagram of one embodiment of a conventional cryptographic computer mezzanine circuit card assembly mated to a host carrier card is shown. More specifically, a crypto host circuit card assembly (CCA) 1, or host board, supports a crypto mezzanine 5, or crypto CCA, comprising various discrete components (e.g., 3, 6, 7, 8), where the crypto CCA 5 is attached to the host CCA 1. In some embodiments, a stiffener frame 2 is present. In conventional cryptos, a TEMPEST boundary 4 encompasses the entire mezzanine CCA 5 with all the discrete components, thereby enabling the crypto mezzanine CCA 5. More specifically, in FIG. 2A, the specific elements in one example include the following: 1: Host Circuit Card Assembly (CCA); 2: mechanical stiffener frame; 3: SDRAM; 4: TEMPEST boundary; 5: Crypto mezzanine Circuit Card Assembly (Crypto CCA); 6: passive/security/filtering components; 7: Flash memory; and 8: a FPGA.

Referring to FIG. 2B, a diagram of one embodiment of a Cryptographic System-In-Package (CSiP) using some of the same or similar components shown in FIG. 2A, according to the principles of the present disclosure is shown. More specifically, the proposed solution removes most of the security burden off of the system while at the same time greatly minimizing the footprint required by the crypto. In certain embodiments, by encapsulating the entire crypto device and TEMPEST boundary, the host system with the embedded CSiP may not need to implement further security measures. For instance, if the CSiP has an embedded TEMPEST shield and power supply filtering, then the host system it would not need these things (as is currently the norm). Furthermore, the implementation of the power supply filtering inside the CSiP can remove the requirement for a “Red” power supply in the system. In certain embodiments, the footprint required for a CSiP could be as much as 75% smaller than the traditional crypto design. One embodiment of the CSiP of the present disclosure provides for the optimal security features of both existing crypto solutions (i.e., embedded and applique) all with the added benefit of a significant footprint reduction and power reduction.

More specifically, in FIG. 2B, one embodiment has the following items: 1′: Host Circuit Card Assembly (CCA); 2′: mechanical stiffener frame; 4′: a TEMPEST Boundary; 12: a SiP including the electronic circuits such as FPGA, SDRAM, flash memory, passive/security/filtering components, and the like; 10: a CSiP containing, a SiP, comprising, for example, a FPGA, SDRAM, flash memory, passive/security/filtering components, and the like, enclosed within the TEMPEST boundary; and 5′: mezzanine Circuit Card Assembly. The CSip 10 occupies a small portion of the mezzanine 5′ allowing for other items to be populated on the mezzanine 5′ or the mezzanine 5′ can be reduced in size such that the host CCA 1′ has more space. In certain embodiments, the CSiP 10 can be made in varied shapes, sizes, form factors, or the like. A mezzanine card 5′ in one example is used to house the CSiP 10, but a CSiP could also comprise a separate board that plugs into a backplane, a stand-alone external applique plug-in module, or the like. The CSiP could even be comingled with other components and other functions on a board, in certain cases. While the mezzanine 5′ is shown as the same size as the conventional one, this could also be reduced in size and provide for more space on the host CCA 1′.

Still referring to FIG. 2B, in one embodiment of the present disclosure the bottom of the package comprises a BGA surround that is tied to ground that runs the perimeter of the CSiP. In one embodiment, the SiP dies are repackaged in a single package that is further surrounded by an internal EMI/TEMPEST shield. This shield may be implemented as a wire mesh or other such device. In certain embodiments, the TEMPEST boundary 4′ is much smaller than in corresponding FIG. 2A (4). In this embodiment, a reduction of the TEMPEST boundary of greater than 3 times is depicted. One analytic study was conducted whereby it was shown that a reduction in size was made from 40.3 cubic centimeters down to 12.3 cubic centimeters. It is to be understood that the present disclosure not only achieves a reduction of the TEMPEST boundary, but also opens up board space that is then available to house components unrelated to crypto functions. Alternatively, if there is no need for more board space to implement other functions, reducing the size of the crypto can allow for a reduction of size for the final product.

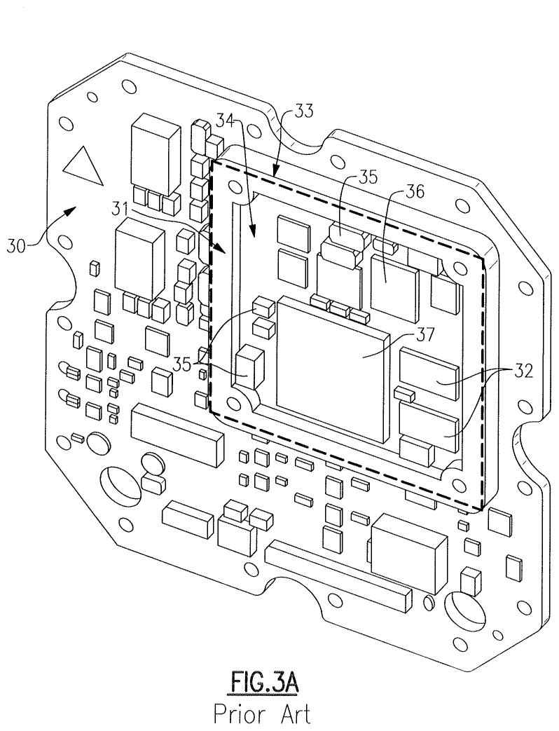

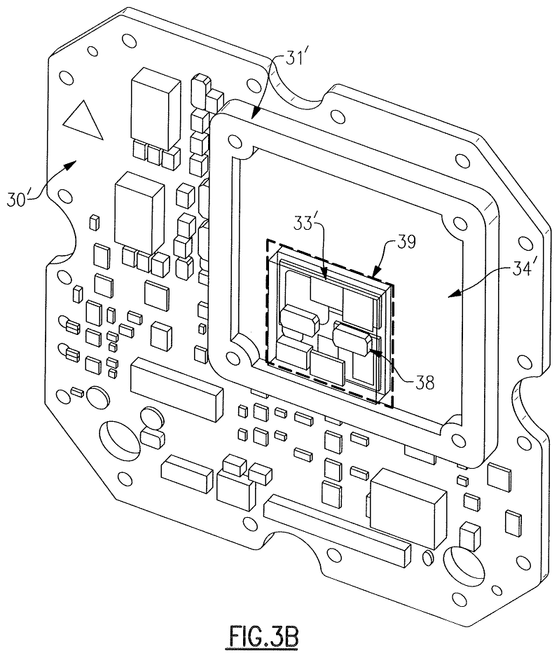

Referring to FIG. 3A, a diagram of one embodiment of a conventional cryptographic computer is shown. More specifically, a crypto host circuit card assembly (CCA) 30, or host board, supports a crypto mezzanine 34, or crypto CCA, comprising various discrete components (32, 35, 37, 37), and the crypto CCA 34 is attached to the host CCA 30. In some embodiments, a stiffener frame 31 is present and is further surrounded by a TEMPEST boundary 33. In conventional cryptos the TEMPEST boundary surrounds the entire crypto mezzanine. More specifically, 30: Host Circuit Card Assembly (CCA); 31: mechanical stiffener frame; 32: SDRAM; 33: a TEMPEST Boundary; 34: Crypto mezzanine Circuit Card Assembly (Crypto CCA); 35: passive/security/filtering components; 36: Flash memory; and 37: a FPGA.

Referring to FIG. 3B, in some embodiments, a Host Circuit Card Assembly (CCA) 30′ performs functions that are necessary for the overall system to complete its mission. An example of some of these functions is as follows. The host CCA receives and transmits RF signals, performs waveform processing, interfaces to one or more military platforms, and provides various indications to the end user. In certain cases, a mechanical stiffener frame 31′ is used to provide added support during heavy vibration experienced on various airborne platforms as well as platforms that vibrate due to gunfire, or the like. A SiP 38 containing components such as FPGA, SDRAM, flash memory, passive/security/filtering components, and the like has, for example, SDRAM, or Standard RAM used by the FPGA. The TEMPEST boundary 33′ is a boundary that defines the confines signals that can be used by an adversary to compromise the system by detection and/or infiltration. This boundary separates an unsecure outside area of the mezzanine 34′ from a secure inside area of the CSiP 39 that houses the SiP components 38 enclosed within the TEMPEST boundary 33′. When placing components and functions within the TEMPEST boundary, a path for secure data to reach the outside world is should be avoided. Therefore, shifting the TEMPEST boundary from the whole mezzanine CCA to a single device is highly desirable due to the fact that it opens up real estate for implementing various other hardware functions without having to worry about security.

The CSiP is the cryptographic computer that provides crypto services to the host CCA. This is a self-contained module that not only provides encryption and decryption services to the host, but also filters all “red” signals thereby ensuring that classified data is never spilled across the TEMPEST boundary. This module also implements various security features that are necessary for military applications.

In certain embodiments, the CSiP is comprised of various discrete components that require substantial board space in order to provide all of the hardware necessary to perform the crypto function e.g., passive/security/filtering components. In some cases, these passive components are capacitors, resistors, inductors, transformers, and the like that are required for proper operation of the crypto. The security components are required to ensure the protection of the classified data, and the filtering components are used to filter all inputs and outputs to ensure that data is not leaked across the TEMPEST boundary. Various filters are also employed to suppress electromagnetic radiation (EMR) from the crypto.

In some cases, non-volatile memory is used by the crypto to store data when power is removed. Flash memory is a solid state (electronic) non-volatile data storage. Flash memory can be electrically written to, read from, and erased. In certain embodiments, a FPGA (Field Programmable Gate Array) is the main processing unit of a crypto. All of the cryptographic functions, communications, controls, and data processing take place in this form of Integrated Circuit (IC).

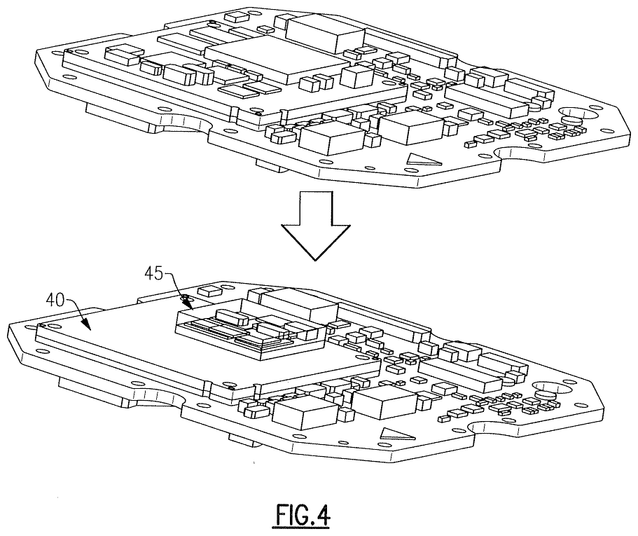

Referring to FIG. 4, a perspective view of one embodiment of a conventional crypto (top) contrasted with one embodiment of a Cryptographic System-In-Package (CSiP) (bottom) according to the principles of the present disclosure using certain similar components is shown. More specifically, considerable space can be gained 40 by utilizing a Cryptographic System-In-Package (CSiP) design approach. In addition to putting the SiP components such as the FPGA die on the top of the package to help manage heat, other parameters such as trace impedance or transmission line effects would need to be evaluated based on specific die being packaged. Placing the FPGA or processor on the top allows the addition of a heatsink to manage the temperature rise of the CSiP. In one embodiment, to fabricate the CSiP, 3D die stacking may be used.

As shown in FIG. 4, the boundary 45 fully encompasses the sides and top surfaces of the SiP components. In one embodiment, the CSiP encapsulation layer comprises a non-metallic polymer with an embedded mesh TEMPEST shield. In some cases, the system comprises a metallic outside case. In one example of operation, the CSiP comprises encryption and decryption processing capabilities such that the host CCA and other components can communicate with the CSiP over the encrypted channels. The communication would be via pins on the ball grid array (BGA) when it is installed on either a host board or mezzanine. This communication could be a standard protocol like Ethernet or a custom interface specific to the application. The underside of the mezzanine CCA that houses the CSiP in one example employs BGAs for electrically connecting the components of a mezzanine CCA, if present, to the host CCA. A perimeter ground plane runs the perimeter of the CSiP portion to minimize signal leakage.

The computer readable medium as described herein can be a data storage device, or unit such as a magnetic disk, magneto-optical disk, an optical disk, or a flash drive. Further, it will be appreciated that the term “memory” herein is intended to include various types of suitable data storage media, whether permanent or temporary, such as transitory electronic memories, non-transitory computer-readable medium and/or computer-writable medium.

It will be appreciated from the above that the invention may be implemented as computer software, which may be supplied on a storage medium or via a transmission medium such as a local-area network or a wide-area network, such as the Internet. It is to be further understood that, because some of the constituent system components and method steps depicted in the accompanying Figures can be implemented in software, the actual connections between the systems components (or the process steps) may differ depending upon the manner in which the present invention is programmed. Given the teachings of the present invention provided herein, one of ordinary skill in the related art will be able to contemplate these and similar implementations or configurations of the present invention.

It is to be understood that the present invention can be implemented in various forms of hardware, software, firmware, special purpose processes, or a combination thereof. In one embodiment, the present invention can be implemented in software as an application program tangible embodied on a computer readable program storage device. The application program can be uploaded to, and executed by, a machine comprising any suitable architecture.

While various embodiments of the present invention have been described in detail, it is apparent that various modifications and alterations of those embodiments will occur to and be readily apparent to those skilled in the art. However, it is to be expressly understood that such modifications and alterations are within the scope and spirit of the present invention, as set forth in the appended claims. Further, the invention(s) described herein is capable of other embodiments and of being practiced or of being carried out in various other related ways. In addition, it is to be understood that the phraseology and terminology used herein is for the purpose of description and should not be regarded as limiting. The use of “including,” “comprising,” or “having,” and variations thereof herein, is meant to encompass the items listed thereafter and equivalents thereof as well as additional items while only the terms “consisting of” and “consisting only of” are to be construed in a limitative sense.

The foregoing description of the embodiments of the present disclosure has been presented for the purposes of illustration and description. It is not intended to be exhaustive or to limit the present disclosure to the precise form disclosed. Many modifications and variations are possible in light of this disclosure. It is intended that the scope of the present disclosure be limited not by this detailed description, but rather by the claims appended hereto.

A number of implementations have been described. Nevertheless, it will be understood that various modifications may be made without departing from the scope of the disclosure. Although operations are depicted in the drawings in a particular order, this should not be understood as requiring that such operations be performed in the particular order shown or in sequential order, or that all illustrated operations be performed, to achieve desirable results.

While the principles of the disclosure have been described herein, it is to be understood by those skilled in the art that this description is made only by way of example and not as a limitation as to the scope of the disclosure. Other embodiments are contemplated within the scope of the present disclosure in addition to the exemplary embodiments shown and described herein. Modifications and substitutions by one of ordinary skill in the art are considered to be within the scope of the present disclosure.

What is claimed:

1. A cryptographic system-in-package, comprising:
a plurality of discrete components located within a single system-in-package (SiP);
a TEMPEST shield surrounding a plurality of sides and a top of the single system-in-package (SiP), wherein the TEMPEST shield is metal and acts as a thermal path to conduct heat off of the system-in-package (SiP); and
a filter for a power supply input to block information leakage on input voltage pins.

2. The cryptographic system-in-package according to claim 1, wherein the power supply is not required to be additionally TEMPEST protected.

3. The cryptographic system-in-package according to claim 1, wherein the plurality of discrete components comprises one or more of a memory, a processor/FPGA, a RAM, and a flash.

4. The cryptographic system-in-package according to claim 3, wherein the plurality of discrete components further comprises a temperature sensor and/or a voltage monitor.

5. The cryptographic system-in-package according to claim 1, wherein the TEMPEST shield further comprises a ball grid array (BGA) with ground encompassing the full perimeter for a bottom of the system-in-package (SiP).

6. The cryptographic system-in-package according to claim 5, wherein a ball spacing is about 1 mm in order to mitigate EMI radiation.

7. The cryptographic system-in-package according to claim 1, further comprising a polymer encapsulation layer for making physical penetration of the system-in-package (SiP) evident via visual inspection.

8. The cryptographic system-in-package according to claim 1, wherein the metal of the TEMPEST shield comprises a microscopic wire mesh covering the system-in-package (SiP).

9. A cryptographic system-in-package, comprising:
a plurality of discrete components located within a single system-in-package (SiP);
wherein a TEMPEST shield:
surrounds a plurality of sides and a top of the single system-in-package (SiP),
is metal and acts as a thermal path to conduct heat off of the system-in-package (SiP); and
comprises a ball grid array (BGA) with ground encompassing the full perimeter for a bottom of the system-in-package (SiP); and
a filter for a power supply input to block information leakage on input voltage pins.

10. The cryptographic system-in-package according to claim 9, wherein the power supply is not required to be additionally TEMPEST protected.

11. The cryptographic system-in-package according to claim 9, wherein a ball spacing is about 1 mm in order to mitigate EMI radiation.

12. The cryptographic system-in-package according to claim 9, further comprising a polymer encapsulation layer for making physical penetration of the system-in-package (SiP) evident via visual inspection.

13. The cryptographic system-in-package according to claim 9, wherein the metal of the TEMPEST shield.

14. The cryptographic system-in-package according to claim 9, wherein the plurality of discrete components comprises one or more of a memory, a processor/FPGA, a RAM, a flash, a temperature sensor, and a voltage monitor.

15. A cryptographic system-in-package, comprising:
a plurality of discrete components located within a single system-in-package (SiP);
wherein a TEMPEST shield:
surrounds a plurality of sides and a top of the single system-in-package (SiP),
comprises a metal microscopic wire mesh covering the system-in-package (SiP) and acts as a thermal path to conduct heat off of the system-in-package (SiP); and
comprises a ball grid array (BGA) with ground encompassing the full perimeter for a bottom of the system-in-package (SiP); and
a filter for a power supply input to block information leakage on input voltage pins.

16. The cryptographic system-in-package according to claim 15, wherein the power supply is not required to be additionally TEMPEST protected.

17. The cryptographic system-in-package according to claim 15, wherein a ball spacing is about 1 mm in order to mitigate EMI radiation.

18. The cryptographic system-in-package according to claim 15, further comprising a polymer encapsulation layer for making physical penetration of the system-in-package (SiP) evident via visual inspection.

19. The cryptographic system-in-package according to claim 15, wherein the plurality of discrete components comprises one or more of a memory, a processor/FPGA, a RAM, a flash, a temperature sensor, and a voltage monitor.
